(19) United States
(12) Patent Application Publication
(10) Pub. No.: US 2025/0034181 A1
(43) Pub. Date: Jan. 30, 2025

(54) SILICON-CONTAINING GROUP 4 PRECURSORS AND DEPOSITION OF METAL-CONTAINING FILMS

(71) Applicant: L'Air Liquide, Société Anonyme pour l'Etude et l'Exploitation des Procédés Georges Claude, Paris (FR)

(72) Inventors: Su-Hyun KIM, Seoul (KR); Wontae NOH, Seoul (KR)

(21) Appl. No.: 18/784,513

(22) Filed: Jul. 25, 2024

Related U.S. Application Data
(60) Provisional application No. 63/529,050, filed on Jul. 26, 2023.

(51) Int. Cl. C07F 7/21; C23C 16/30

(52) U.S. Cl. CPC C07F 7/21; C23C 16/30

(57) ABSTRACT

Disclosed are Metal-containing film forming compositions comprising metal precursors having the formula M[N(R¹)A(R²)(R³)(NR⁴R⁵)]ₐ(L¹)_{b}(L²)_{c}(L³)_{d}. These precursors are useful as single-source precursors for depositing metal silicate via vapor deposition processes.

### CROSS REFERENCE TO RELATED APPLICATIONS

This application claims the benefit of priority under 35 U.S.C. § 119 (a) and (b) to U.S. Provisional Patent Application No. 63/529,050, filed Jul. 26, 2023, the entire contents of which are incorporated herein by reference.

### TECHNICAL FIELD

The disclosure relates to vapor deposition of metal silicate materials, in particular for high-k applications in semiconductors.

### BACKGROUND ART

As electronic devices become miniaturized, efforts are being made to reduce leakage current and to use materials with higher permittivity. In this respect, the development of a precursor is directly related to the advance in semiconductor technology. So far, Ta₂O₅, TiO₂, ZrO₂, HfO₂, ZrSiₓO_{y} and HfSiₓO_{y} have been typically used as a high-k material to replace the SiO₂ (Thin Solid Films 516 (2008) 1563). However when it comes to Ta₂O₅ and TiO₂, there is a defect that they are not thermally stable when they contact with silicon substrates (Jpn. J. Appl. Phys. Vol. 41 (2002) 690).

In terms of reducing the leakage current, metal-silicate films are preferred rather than single-metal oxide films. In the past, two kinds of precursors were used to form ZrSiₓO_{y} and HfSiₓO_{y} films, e.g. Hf(NEt₂)₄/SiH(NEt₂)₃, Hf(NEt₂)₄/Si(OⁿBu)₄, Hf(O^{t}Bu)₄/SiH₄, Hf(NEt₂)₄/Si(OⁿBu)₄ (Colombo, Appl. Phys. Lett. 80 (2002) 2362), (Thin Solid Films 416 (2002) 208), (Mater. Chem. 14 (2004) 391). However, since the volatility and decomposition temperatures of the two types of precursors are different, there is difficulty to set the process temperature. Also, it is hard to get a film uniformity and good step coverage.

To overcome these disadvantages, single-source precursors containing both Hf and Si atoms have been used to form HfSiₓO_{y} films, such as Hf(OSi^{t}BuMe₂)₂, Hf(thd)₂[N(SiMe₃)₂]₂, Hf(thd)₂(OSi^{t}BuMe₂)₂ (Microel. Reliab. 45 (2005) 819), (Polyhedron 24 (2005) 3066). Also Zr precursors with silylamine ligand, such as Zr(NMe₂)₂(EtNSiMe₃)₂, Zr(NEtMe)₂(EtNSiMe₃)₂, etc. were patented in Korea (KR101216068).

We describe herein the synthesis and characterization of novel Group 4 precursors containing other atoms such as Si and Ge. These are useful as new single source precursors for metal silicates and other materials.

### SUMMARY

The disclosed precursor compounds include Si and Ge atom as a substituent and have a general formula:

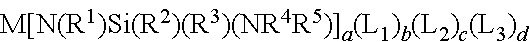

In the above formula:
M=a transition metal, a rare earth element (lanthanide elements, Y, Sc), an alkali metal, or an alkaline earth metal;
A=C, Si, Ge
R¹, R², R³, R⁴, R⁵ are each independently selected from H, C₁-C₁₀ branched or linear alkyl or fluoroalkyl chain;
L¹ is/are −1 anionic ligands, that are typically selected from halides, —OR^{a}, —NR^{a}R^{b}, amidinate group, beta diketonate, non-fluorinated dienyl group, alkyl group; with each of R^{a} and R^{b} being independently selected from the group consisting of H and —(CX₂)ₚCY₃; each X is independently H or F, each Y is independently H or F, p=0-10;
L² is/are −2 anionic ligands, that are typically selected from imido groups ═N—R^{c} (R^{c}═C₁-C₆ linear, cyclic, or branched), diamines (e.g. R^{c}—N—C₂H₄—N—R^{c}) or Cp linkaged amine (Cp-CₓH_{y}—N—R^{c});
L³ is/are neutral ligands or adducts, selected from 1) Oxygen based ligands: Aliphatic and aromatic—alcohols, diols, ethers, epoxides, aldehydes, ketones, carboxylic acids, enols, esters, anhydrides, phenols, substituted phenols; 2) Nitrogen based ligands: Aliphatic and aromatic—amines, imines, imides, amides, azides, cyanates, nitrile, nitrate, nitrite, nitrogen containing heterocycles; 3) Sulfur based ligands: aliphatic and aromatic—thiols, sulfides, disulfide, sulfoxide, sulfone, thiocyanates, isothiocyanates, thioesters; 4) Phosphorus based ligands: aliphatic and aromatic phosphines, phosphonic acid, phosphodiesters; 5) Boron based ligands: aliphatic and aromatic—boronic acid, boronic ester, borinic esters; 6) carbon based ligands: aliphatic-alkenes, alkynes and benzene derivatives. 7) Halide containing organic molecules, inorganic halide, e.g. I₂, H₂O vapor, H₂ gas, CO gas, CS gas, NOx gas, any radical form of gases at RT.

In the above formula:
a+b+2c=the oxidation state of the metal M
a, b, c, d are each ≥0

In some embodiments, the neutral ligand L³ is covalently linked to L¹ or L².

### BRIEF DESCRIPTION OF DRAWINGS

For a further understanding of the nature and objects for the present invention, reference should be made to the following detailed description, taken in conjunction with the accompanying drawings, in which like elements are given the same or analogous reference numbers and wherein:

FIG. 1 is a ThermoGravimetric Analysis (TGA) graph demonstrating the percentage of weight with increasing temperature of Zr[N(iPr)SiMe₂(NMe₂)](NMe₂)₃; and

FIG. 2 is a Differential Scanning calorimetry (DSC) of Zr[N(iPr)SiMe₂(NMe₂)](NMe₂)₃.

### EXAMPLES

### Example 1

### Synthesis of Chloro(Dimethylamino)Dimethyl Silane

Dichlorodimethylsilane (9.374 g, 0.0726 mol) was dissolved in 60 mL of pentane and cooled to −65° C. Bis(dimethylamino)dimethylsilane (10.62 g, 0.0726 mol) dissolved in 20 ml of pentane was added to the dichlorodimethylsilane. The mixture was stirred at room temperature overnight. After the reaction, the solvent was dried under vacuum conditions. Pale yellow liquid was obtained in 59% yield (11.7 g). The material was characterized by NMR ¹H (δ, ppm, C₆D₆): 2.28 (s, 6H). 0.28 (s, 6H).

### Synthesis of Dimethyl(Dimethylamino)(Isopropylamino)Silane

Isopropyl amine (2.36 g, 0.0399 mol) was dissolved in 30 mL of diethyl ether and cooled to −65° C. Methyl lithium (1.6 M in ether solution) (23.8 mL, 0.0381 mol) was added to the isopropyl amine. The mixture was stirred at room temperature for 3 hours. Chloro(dimethylamino)dimethyl silane (5 g, 0.0363 mol) was dissolved in 30 mL diethyl ether and cooled to −65° C. lithiated isopropylamine solution was added to the chloro(dimethylamino)dimethyl silane. The mixture was stirred at room temperature overnight. After the reaction, filter the lithium chloride and then the filtrate was dried under vacuum condition. Orange liquid was obtained in 87% yield (5.05 g). The material was characterized by NMR ¹H (δ, ppm, C₆D₆): 2.99 (sept, 1H). 2.49 (s, 6H). 1.00 (d, 6H). 0.29 (br, 1H). 0.08 (s, 6H).

### Example 2

### Synthesis of Zr[N(iPr)SiMe₂(NMe₂)](NMe₂)₃

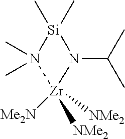

TDMAZ (6 g, 0.0224 mol) and 40 mL of toluene were added in the Schlenk flask and cooled to −65° C. SiMe₂(N(iPr))(NMe₂) ligand (4.0 g, 0.02467 mol) was added to the TDMAZ solution. The mixture was stirred overnight at room temperature. After the reaction, the solvent was removed under vacuum conditions. The crude was brown sticky solid. The material was then purified by sublimation up to 100° C. @ 35 mTorr to give 4.9 g (57%) of sticky pale yellow solid. The material was characterized by NMR ¹H (δ, ppm, C₆D₆): 3.55 (sept, 1H). 3.05 (s, 18H). 2.24 (s, 6H). 1.23 (d, 6H). 0.15 (s, 6H).

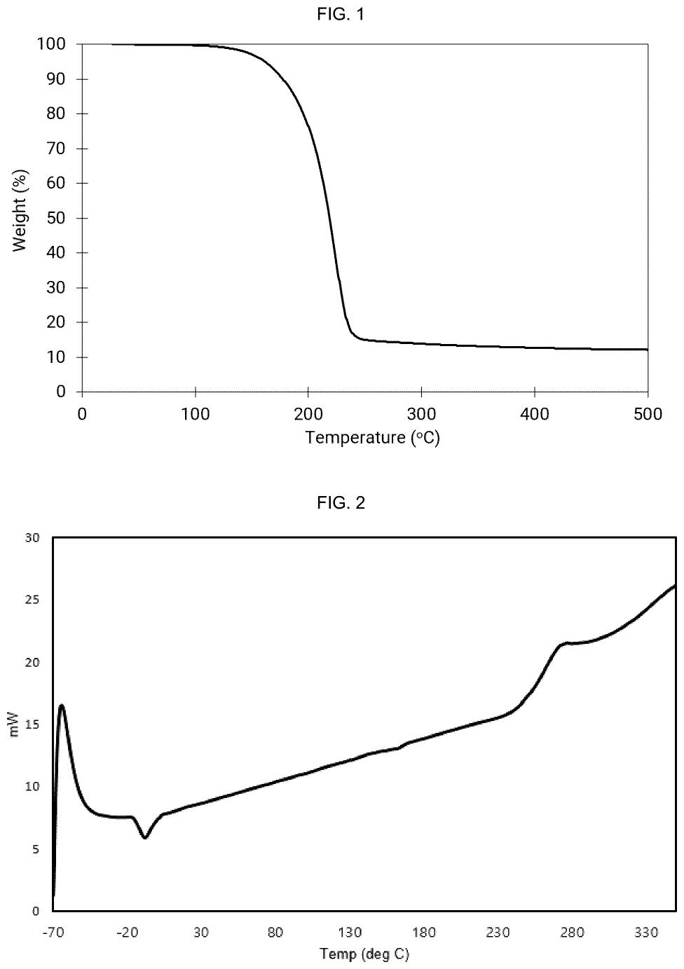

The purified Zr[N(iPr)SiMe₂(NMe₂)](NMe₂)₃ left a 0.1% residual mass during open-cup TGA analysis measured at a temperature rising rate of 10° C./min in an atmosphere which flows nitrogen at 200 mL/min. These results are shown in FIG. 1, which is a TGA graph illustrating the percentage of weight upon temperature increase. Onset temperature of decomposition (247° C.) of the product was measured by Differential scanning calorimetry (DSC), which are shown in FIG. 2.

### INDUSTRIAL APPLICABILITY

The present invention is at least industrially applicable to forming high-k materials in semiconductors.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed. Furthermore, if there is language referring to order, such as first and second, it should be understood in an exemplary sense and not in a limiting sense. For example, it can be recognized by those skilled in the art that certain steps can be combined into a single step.

The singular forms “a”, “an” and “the” include plural referents, unless the context clearly dictates otherwise.

“Comprising” in a claim is an open transitional term which means the subsequently identified claim elements are a nonexclusive listing (i.e., anything else may be additionally included and remain within the scope of “comprising”). “Comprising” as used herein may be replaced by the more limited transitional terms “consisting essentially of” and “consisting of” unless otherwise indicated herein.

“Providing” in a claim is defined to mean furnishing, supplying, making available, or preparing something. The step may be performed by any actor in the absence of express language in the claim to the contrary.

Optional or optionally means that the subsequently described event or circumstances may or may not occur. The description includes instances where the event or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range.

All references identified herein are each hereby incorporated by reference into this application in their entireties, as well as for the specific information for which each is cited.

### Technical Definitions

As used herein, “room temperature” in the text or in a claim means from approximately 20° C. to approximately 25° C.

The term “ambient conditions” refers to an environment temperature (i.e., ambient temperature) approximately 20° C. to approximately 25° C. and an environment pressure (ambient temperature) approximately 1 atm or 1 bar.

The term “substrate” refers to a material or materials on which a process is conducted. The substrate may also have one or more layers of differing materials already deposited upon it from a previous manufacturing step.

One of ordinary skill in the art will recognize that the terms “film” or “layer” used herein refer to a thickness of some material laid on or spread over a surface and that the surface may be a trench or a line.

The standard abbreviations of the elements from the periodic table of elements are used herein. It should be understood that elements may be referred to by these abbreviations (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to help better identify the molecules disclosed.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed. Furthermore, if there is language referring to order, such as first and second, it should be understood in an exemplary sense and not in a limiting sense. For example, it can be recognized by those skilled in the art that certain steps can be combined into a single step.

The singular forms “a”, “an” and “the” include plural referents, unless the context clearly dictates otherwise.

“Comprising” in a claim is an open transitional term which means the subsequently identified claim elements are a nonexclusive listing (i.e., anything else may be additionally included and remain within the scope of “comprising”). “Comprising” as used herein may be replaced by the more limited transitional terms “consisting essentially of” and “consisting of” unless otherwise indicated herein.

“Providing” in a claim is defined to mean furnishing, supplying, making available, or preparing something. The step may be performed by any actor in the absence of express language in the claim to the contrary.

Optional or optionally means that the subsequently described event or circumstances may or may not occur. The description includes instances where the event or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range.

All references identified herein are each hereby incorporated by reference into this application in their entireties, as well as for the specific information for which each is cited.

What is claimed is:

1. A chemical suitable for use as a vapor phase deposition precursor, the chemical have a formula 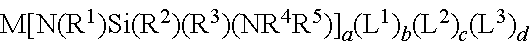
wherein:
M=a transition metal, a rare earth element (lanthanide elements, Y, Sc), an alkali metal, or an alkaline earth metal; a+b+2c=the oxidation state of the metal M; and a, b, c, d are each ≥0;
A=C, Si, Ge
R¹, R², R³, R⁴, R⁵ are each independently selected from H, C₁-C₁₀ branched or linear alkyl or fluoroalkyl chain;
L¹ is/are −1 anionic ligands, that are typically selected from halides, —OR^{a}, —NR^{a}R^{b}, amidinate group, beta diketonate, non-fluorinated dienyl group, alkyl group; with each of R^{a} and R^{b} being independently selected from the group consisting of H and —(CX₂)ₚCY₃; each X is independently H or F, each Y is independently H or F, p=0-10;
L² is/are −2 anionic ligands, that are typically selected from imido groups ═N—R^{c} (R^{c}═C₁-C₆ linear, cyclic, or branched), diamines (e.g. R^{c}—N—C₂H₄—N—R^{c}) or Cp linkaged amine (Cp-CₓH_{y}—N—R^{c}); and
L³ is/are neutral ligands or adducts, selected from 1) Oxygen based ligands: Aliphatic and aromatic—alcohols, diols, ethers, epoxides, aldehydes, ketones, carboxylic acids, enols, esters, anhydrides, phenols, substituted phenols; 2) Nitrogen based ligands: Aliphatic and aromatic—amines, imines, imides, amides, azides, cyanates, nitrile, nitrate, nitrite, nitrogen containing heterocycles; 3) Sulfur based ligands: aliphatic and aromatic—thiols, sulfides, disulfide, sulfoxide, sulfone, thiocyanates, isothiocyanates, thioesters; 4) Phosphorus based ligands: aliphatic and aromatic phosphines, phosphonic acid, phosphodiesters; 5) Boron based ligands: aliphatic and aromatic—boronic acid, boronic ester, borinic esters; 6) carbon based ligands: aliphatic-alkenes, alkynes and benzene derivatives. 7) Halide containing organic molecules, inorganic halide, e.g. 12, H₂O vapor, H₂ gas, CO gas, CS gas, NOx gas, any radical form of gases at RT.

2. The chemical of claim 1, having at least one of L¹ or L² and at least one of L³.

3. The chemical of claim 2, wherein the least one of L³ is covalently linked to the at least one of L¹ or L².

4. The chemical of claim 1, wherein A is selected from Ge or Si.

5. The chemical of claim 1, wherein A is Si.

6. The chemical of claim 1, wherein the chemical is Zr[N(iPr)SiMe₂(NMe₂)](NMe₂)₃.

7. A composition, comprising a vapor phase of the chemical of claim 1.

8. The composition of claim 7, further comprising a carrier gas, preferably comprising an inert gas selected from Helium, Nitrogen, Argon, Neon, Xenon and combinations thereof.

9. A method of vapor phase depositing a metal silicate or a metal-germanium containing material on a surface, the method comprising:
a. providing a substrate having a surface, and
b. exposing the substrate to a vapor phase of the chemical of claim 1, under conditions suitable to form a deposited material, comprising M and A, on the surface.

10. The method of claim 9, wherein the deposited material is a contiguous and conformal film or layer on the surface of the substrate.

11. The method of claim 9, further comprising exposing the surface of the substrate to a gaseous co-reactant capable of acting as a reducing agent, contemporaneously with, or subsequent to claim 14, step b).

12. The method of claim 11, wherein the gaseous co-reactant is ammonia or hydrogen.

13. The vapor phase method of claim 9, wherein the vapor phase method is a chemical vapor phase deposition or an atomic layer deposition.
